(19) United States
(12) Patent Application Publication
(10) Pub. No.: US 2008/0054300 A1
(43) Pub. Date: Mar. 6, 2008

(54) Body contact structure and method for the reduction of drain lag and gate lag in field effect transistors

(76) Inventors: Philip Gene Nikkel, Loveland, CO (US); John S. Wei, Cupertino, CA (US)

Correspondence Address: Kathy Manke;Avago Technologies Limited, 4380 Ziegler Road, Fort Collins, CO, 80525, US

(21) Appl. No.: 11/480,609

(22) Filed: Jun. 30, 2006

(51) Int. Cl. H01L 31/00

(52) U.S. Cl. 257/192

(57) ABSTRACT

A field effect transistor is formed on a substrate and includes a semiconductor channel region formed over the substrate and a metallic source region formed on the channel region. A metallic drain region is formed on the channel region and a metallic gate region formed on the channel region between the source and drain regions. A first metallic body contact region is formed adjacent the drain region and extending through the channel region to contact the substrate. The field effect transistor may further include a second metallic body contact region formed adjacent the source region and extending through the channel region to contact the substrate.

### TECHNICAL FIELD

The present invention relates generally to field effect transistors, and more specifically to the reduction of drain lag and gate lag in such transistors.

### BACKGROUND OF THE INVENTION

Field effect transistors (FETs) are utilized in many common electronic devices, such as cell phones, personal and pocket computers, and personal digital assistants (PDAs). FIG. 1 illustrates a simplified cross-sectional view of a conventional metal semiconductor FET (MESFET) 100 formed on a substrate 102. The MESFET 100 includes a number of buffer layers 104 formed on the substrate 102 and an N-type channel region 106 formed on these buffer layers. A metallic drain region 108 and metallic source region 110 are formed spaced apart on the channel region 106 to define a channel between the two regions. A metallic gate region 112 is formed on the channel region 106 between the metallic drain and source regions 108 and 110. In the example of FIG. 1, a supply voltage Vdd is applied to the drain region 108 along with a reference voltage Vss applied to the source region 110 and a positive gate voltage Vg to the gate region 112.

Before the application of any gate voltage Vg, the presence of the gate region 112 depletes the channel region 106 of electrons in a region underneath called depletion region 114 which cuts off electrical conduction though the channel region 106. In operation, when the gate voltage Vg has a value such that a gate-to-source voltage Vgs exceeds a threshold voltage, the depletion region 114 retracts back toward the gate region 112, thus enabling partial electrical conduction through the channel region 106. A drain-to-source current Ids then flows from the drain region 108 through the depletion layer 114 to the source region 110, turning ON the MESFET 100. When the gate voltage Vg has a value such that the gate-to-source voltage Vgs is less than the threshold value, the depletion layer 114 is too extensive to allow current Ids to flow through the channel 106 from the drain to source regions 108 and 110 and the MESFET 100 is turned OFF.

A detailed discussion of the general operation of a MESFET and the physical phenomena responsible for such operation are well understood by those skilled in the art. Thus, for the sake of brevity, this operation will not be described in more detail herein since it is not necessary for one skilled in the art to understand the present invention.

When the channel region 106 is formed from gallium arsenide (GaAs) and other III-V materials on the electrically insulating substrate 102, an undesirable phenomena can occur which adversely affects the operation of the MESFET. More specifically, a phenomenon known as “drain lag” can occur when the voltage applied to the drain region 108 of the MESFET 100 changes very abruptly while the gate-to-source voltage Vgs remains constant. This phenomenon results in undesirable variations in the drain-to-source current Ids of the MESFET 100 and is alternatively referred to as drain current hysteresis, drain lag, or drain conductance transients. When using the MESFET 100 in certain wireless transmission applications, such as in code division multiple access (CDMA) and wideband CDMA (WCDMA) systems, these relatively large variations or transients in the current Ids cannot be tolerated, which renders the MESFET unusable in these types of applications.

The phenomenon of drain lag is caused by an extraneous electrical potential from energetic charges (holes or electrons) 116 scattered out of the channel region 106 and into the substrate 102, as illustrated in FIG. 1. These charges 116 scatter out of the channel region 106 during operation of the MESFET 100 and become trapped in the substrate 102 or trapped at the interface of the channel region and substrate. Once trapped, it takes time for these charges 116 to escape from the substrate 102. As long as the charges 116 are trapped, an extra biasing electric field caused by these charges acts as a separate gate bias voltage from below the channel region 106. This separate gate bias voltage causes a depletion region 118 in the channel region 106, which reduces the drain-to-source current Ids flowing through the channel region 106.

When the supply voltage Vdd applied to the drain region 108 changes, the number of charges 116 scattered out of the channel region 106 decreases or increases in proportion to the change in the supply voltage Vdd. As a result, the extra potential caused by these trapped charges 116 also changes after a delay that is determined by the rate at which the charges are released from the substrate 102. This delay or “lag” is directly reflected in a lag of the change in the drain-to-source current Ids after a change in the supply voltage Vdd or other voltage applied to the drain region 108.

The MESFET 100 may also experience a similar and related hysteresis phenomenon typically referred to as “gate lag.” Gate lag can occur where the gate voltage Vg is a low duty cycle abruptly varying signal, which results in sudden changes in the gate-to-source voltage Vgs. After such a change in the gate-to-source voltage Vgs, the drain-to-source current Ids settles to a new steady state value after a delay. Because the drain-to-source current Ids determines the number of trapped charges 116, a steady state condition for the number of trapped charges is achieved for a given drain-to-source current. Any change in the supply voltage Vdd or change in the gate voltage Vg will result in a new value for the drain-to-source current Ids, with the prior value for the drain-to-source current and the corresponding trapped charges 116 having a hysteresis affect on the new value.

Where the channel region 106 is a III-V material such as gallium arsenide, electrical charges are more likely to be trapped by material defects in the formation of the MESFET 100 than by an errant profile of electrical potential, as will be understood by those skilled in the art. Furthermore, it is well known that material defects release trapped charges at characteristic rates that are little affected by electrical voltages applied to the MESFET 100, which is another way of saying defects which result in trapped charges dominate the release time of such trapped charges. Prior approaches of reducing gate lag have accordingly focused on reducing the effects of such material defects.

The most effective prior approach of reducing the drain lag in the MESFET 100 where the channel region 106 is a III-V material utilizes a layer that repels scattered charges 116 (electrons or holes) as these charges approach the substrate 102. Such a layer serves to isolate the channel region 106 from substrate 102 to prevent the trapping of charges 116 in the substrate which, in turn, prevents any bias potential caused by such trapped charges from modulating the drain-to-source current Ids. One example of such a layer is a low temperature buffer layer which is an epitaxially grown on the substrate at a fairly low temperature so that the layer is inhomogeneous. As a result, electrical potentials from aggregates of metal in the buffer layer set up barriers to repel incoming electrical charges. A second example is a buried p-channel layer that has ions implanted below the N-type channel region 106. Because the channel region is N-type, the p-n junction thus formed underneath the channel region keeps charges from being injected into the substrate 102.

Both these prior approaches have cost drawbacks from a manufacturing perspective. The low temperature buffer layer doubles the epitaxial growth time for the MESFET 100 and hence increases the cost of materials. The buried p-channel approach adds two ion implantation steps, an anneal step, plus a contact deposition to the p-type channel, leading to a higher manufacturing cost for the MESFET 100. Moreover, from a performance considerations perspective of the MESFET 100, modifying the material in contact with the channel region 106 may undesirably modify the direct current (DC) or radio frequency (RF) performance of the MESFET through changes in parasitic electrical parameters, such as parasitic capacitances, of the MESFET.

There is a need for eliminating or reducing the effects of drain lag and gate lag in MESFETs.

### SUMMARY OF THE INVENTION

According to one aspect of the present invention, a field effect transistor is formed on a substrate. The transistor includes a semiconductor channel region formed over the substrate and a metallic source region formed on the channel region. A metallic drain region is formed on the channel region and a metallic gate region formed on the channel region between the source and drain regions. A first metallic body contact region is formed adjacent the drain region and extending through the channel region to contact the substrate. The field effect transistor may further include a second metallic body contact region formed adjacent the source region and extending through the channel region to contact the substrate.

### BRIEF DESCRIPTION OF THE DRAWINGS

FIG. 1 is a simplified cross-sectional view of a conventional metal semiconductor FET (MESFET) formed on a substrate.

FIG. 2 is a simplified cross-sectional view of a MESFET including source and drain body contact regions that reduce the undesirable affects of drain lag and gate lag according to one embodiment of the present invention.

FIG. 3 is a graph illustrating power output as a function of time for a microwave monolithic integrated circuit (MMIC) including the MESFET of FIG. 2 which illustrates the reduced drain lag for the MESFET due to the source and drain body contacts.

FIG. 4 is a graph illustrating in more detail the power output as a logarithmic function of time for the MMIC of FIG. 3 that more clearly illustrates the reduced drain lag of the MESFET in the MMIC due to the source and drain body contacts.

FIG. 5 is a graph illustrating transistor amplifier current as a function of time for an MMIC including the MESFET of FIG. 2 which shows reduced gate lag of the MESFET when a rapid change in gate-to-source voltage occurs.

### DETAILED DESCRIPTION OF PREFERRED EMBODIMENTS

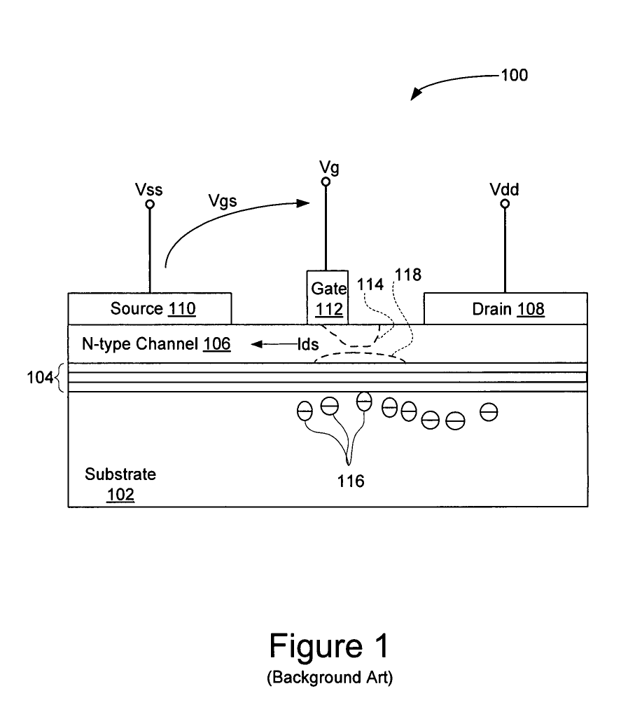

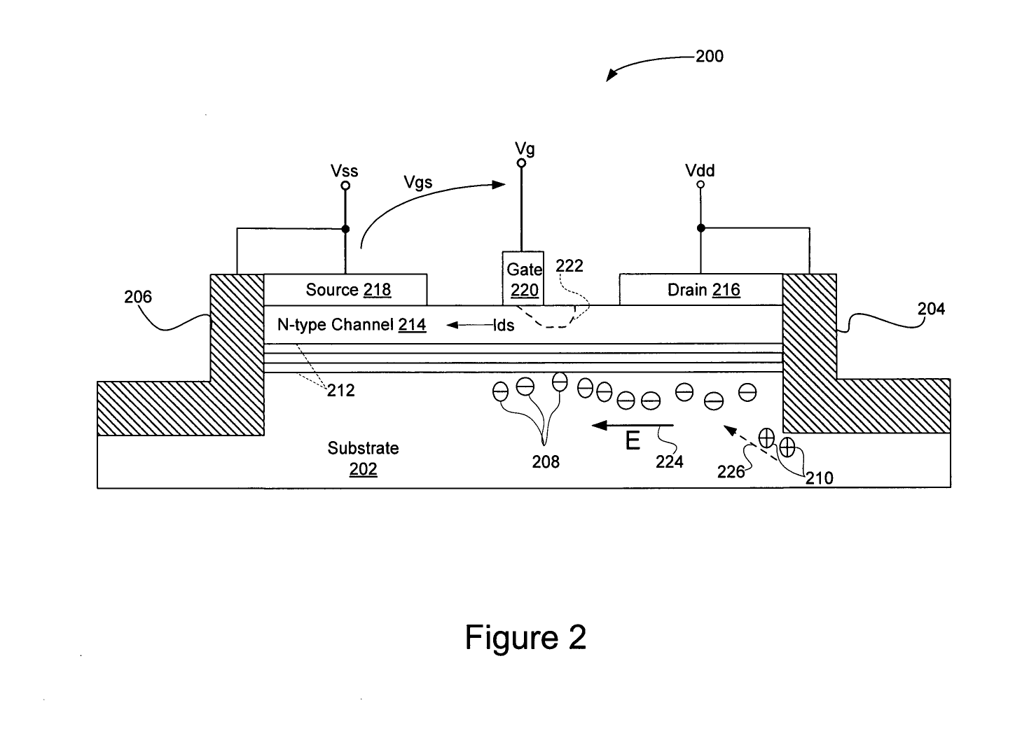

FIG. 2 is a simplified cross-sectional view of a MESFET 200 formed in a body or substrate 202 and including a drain body contact region 204 and source body contact region 206 according to one embodiment of the present invention. Each of the body contact regions 204 and 206 contacts the substrate 202. A supply voltage Vdd is applied to the drain body contact region 204 and a reference voltage Vss is applied to the source body contact region 206, each of these applied voltages establishing an electric field E in the substrate 202. This electric field E significantly modifies the nature of the traps in which electrons 208 are trapped, allowing these charges to escape from the substrate much more quickly than in the conventional MESFET 100 of FIG. 1. Removal of the electrons 208 and the supplying of positive charge carriers or holes 210 from the drain body contact region 204 to neutralize the electrons prevents the trapped electrons from establishing an unwanted biasing electric field and corresponding gate bias voltage, as previously discussed with reference to FIG. 1. The rapid removal or neutralization of these trapped electrons 208 results in a reduced drain lag and gate lag for the MESFET 200, as will be described in more detail below. In a preferred embodiment of the MESFET 200, a Schoftky type of contact is used for the contacts between each of the contact regions 204 and 206 and a channel region 214. Because the substrate 202 can be semi-insulating, an ohmic type of contact normally does not allow enough current to flow through the substrate 202. A Schottky contact, in contrast, can inject charges efficiently into the substrate 202 even if the latter is semi-insulating. However, if an ohmic type of contact allows efficient charge injection into substrate 202, it may be used for either or both of the contact regions 204 and 206.

In the following description, certain details are set forth in conjunction with the described embodiments of the present invention to provide a sufficient understanding of the invention. One skilled in the art will appreciate, however, that the invention may be practiced without these particular details. Furthermore, one skilled in the art will appreciate that the example embodiments described below do not limit the scope of the present invention, and will also understand that various modifications, equivalents, and combinations of the disclosed embodiments and components of such embodiments are within the scope of the present invention. Embodiments including fewer than all the components of any of the respective described embodiments may also be within the scope of the present invention although not expressly described in detail below. Finally, the operation of well known components and/or processes has not been shown or described in detail below to avoid unnecessarily obscuring the present invention.

The MESFET 200 includes a number of buffer layers 212 formed on the substrate 202 and the N-type channel region 214 of gallium arsenide or other III-V material formed on these buffer layers. A metallic drain region 216 and metallic source region 218 are formed spaced apart on the channel region 214 to define a channel between the two regions. A metallic gate region 220 is formed on the channel region 214 between the metallic drain and source regions 216 and 218. In the example of FIG. 2, the supply voltage Vdd is also applied to the drain region 216 and the reference voltage Vss is applied to the source region 218. A gate voltage Vg is applied to the gate region 220 to turn the MESFET 2000N and OFF and control the flow of a drain-to-source current Ids between the drain and source regions 216 and 218. In the MESFET 200 the substrate 202 may be an N-type or a P-type material.

In operation, when the gate voltage Vg has a value such that a gate-to-source voltage Vgs exceeds a threshold voltage, the depletion region 222 retracts back toward the gate region 220, thus enabling partial electrical conduction through the channel region 214. A drain-to-source current Ids then flows from the drain region 216 around the depletion layer 222 to the source region 218, turning ON the MESFET 200. When the gate voltage Vg has a value such that the gate-to-source voltage Vgs is less than the threshold value, the depletion layer 222 is too extensive to allow a significant current Ids to flow through the channel 214 from the drain to source regions 216 and 218 and the MESFET 200 is turned OFF.

As previously discussed with reference to the MESFET 100 of FIG. 1, during operation of the MESFET 200 some energetic electrons 208 are trapped in the substrate 202. In the MESFET 200, however, the drain body contact region 204 and source body contact region 206 accelerate the release of any electrons 208 from traps in the substrate 208 or at the interface of the buffer layers 212 and the substrate. More specifically, the source and drain body contact regions 204 and 206 establish an electric field E in the substrate 202 as shown in FIG. 2. The positive supply voltage Vdd applied to the drain body contact region 204 and negative (or ground) reference voltage Vss applied to the source body contact region 206 result in the electric field E having a direction from right-to-left as indicated by arrow 224. As a result, electrons 208 move generally from left-to-right or toward the drain body contact region 204 due to the electric field E. Similarly, holes 210 are supplied from the drain body contact region 204 and move generally from right-to-left toward the electrons 208 to neutralize such electrons. In sum, the body contact regions 204 and 206 remove the electrons 208 sufficiently quickly to significantly reduce any transient effect on the drain-to-source current Ids caused by these trapped electrons. In this way, the body contacts 204 and 206 reduce the gate lag and drain lag of the MESFET 200.

With the MESFET 200, only the body contact regions 204 and 206 need be formed in addition to the other conventional components of the MESFET. This is easily done through trenches formed on the drain region 216 and source region 218 sides of the MESFET 200. No buried p-channel ion implant is needed. Moreover, with the MESFET 200 and other embodiments of the present invention, the internal geometry of the device, namely the dimension of all components of the device except the body contact regions 204 and 206, is unchanged. Moreover, no additional material or process steps are required except, for example, for a trench etch in which to form the metallic body contact regions 204 and 206. Therefore, embodiments of the present invention significantly enhance the performance of the MESFETs with little cost penalty in redesign or processing and can be easily incorporated in almost all III-V material field effect transistors with no increase in die size.

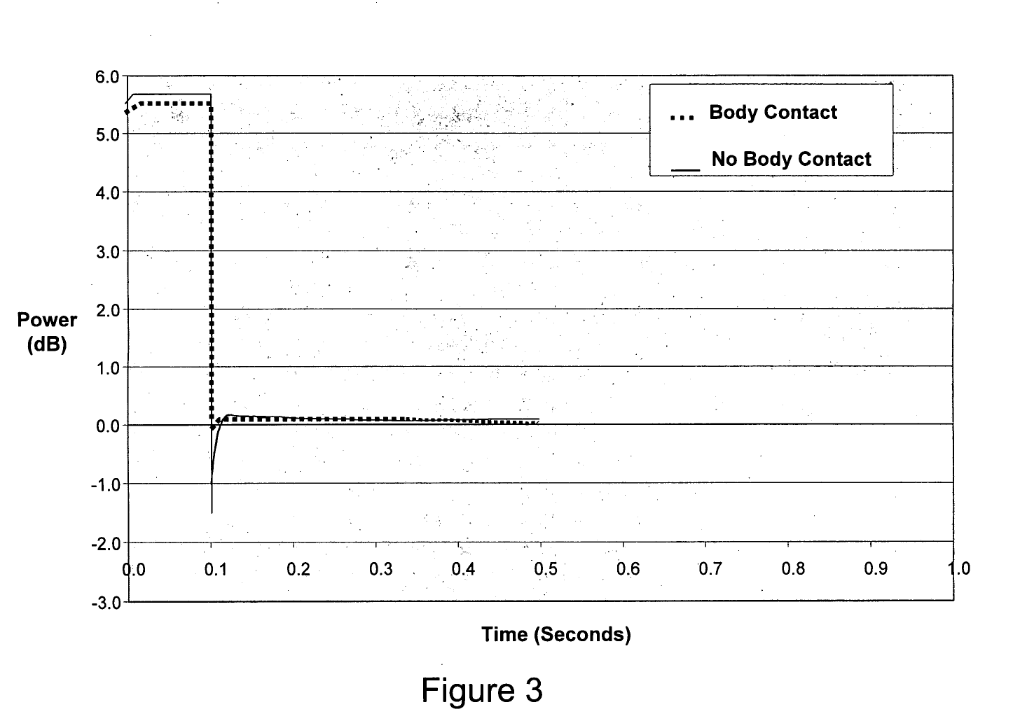

FIG. 3 is a graph illustrating power output as a function of time for a microwave monolithic integrated circuit (MMIC) including the MESFET 200 of FIG. 2. This graph illustrates the reduced drain lag for the MESFET 200 due to the drain and source body contacts 204 and 206. The power output of the MMIC is shown along the vertical axis of the graph and is a function of the drain-to-source current Ids of the MESFET 200. Time is shown along the horizontal axis and at a time 0.1 seconds the voltage (Vdd in FIG. 2) applied to the drain region 216 is switched from 3.6 volts to 1 volt. The power output of the MMIC initially drops from just greater than 5 dBm on the vertical axis, as shown by the dotted line, to just below 0 dBm before recovering to the final power level of 0 dBm. MESFETs that do not have the body contact regions 204 and 206 exhibit a larger overshoot of the power output to approximately −1.5 dBm, as shown by the solid line, before recovering to the final power level of 0 dBm.

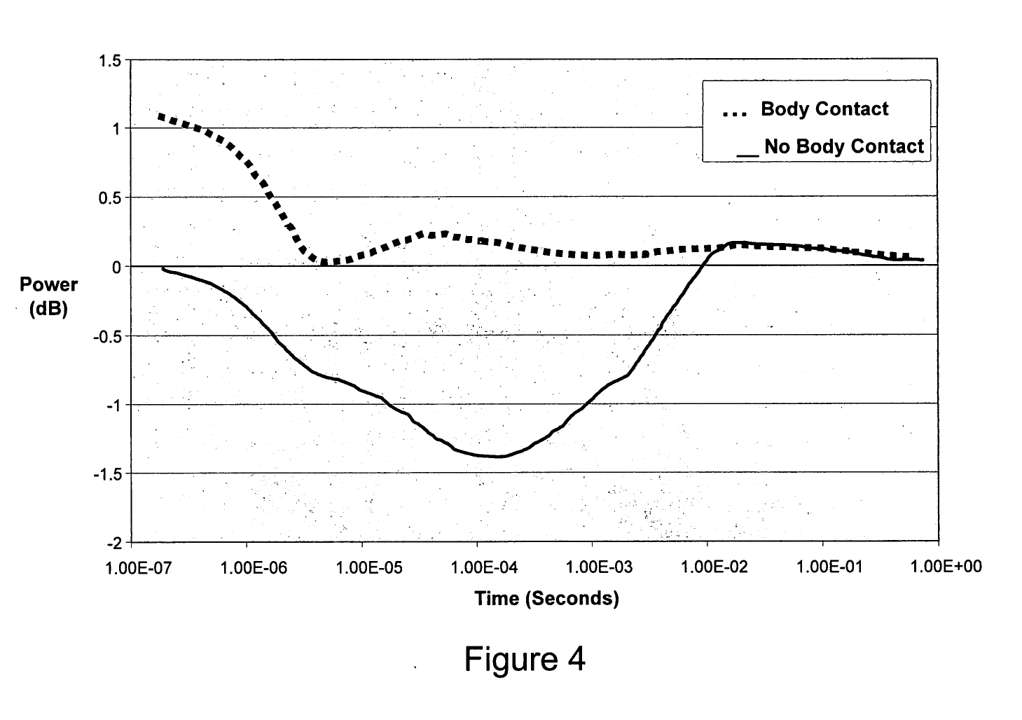

FIG. 4 is a graph illustrating in more detail the power output as a logarithmic function of time for the MMIC discussed with reference to FIG. 3. FIG. 4 more clearly illustrates the reduced drain lag of the MESFET 200 in the MMIC due to the source and drain body contacts 204 and 206. The graph shows two MESFETs with vastly different responses to the change in the voltage Vdd applied to the drain region 216 (FIG. 2) of the device. The first MESFET 200 includes the drain and source body contact regions 204 and 206. The upper line for this device shows a total power fluctuation of only about 0.2 dBm after the transition of the voltage Vdd ends at 1E-5 seconds and before settling to 0 dBm. In contrast, the second MESFET 200 does not include the body contact regions 204 and 206. The lower line for this device shows, after the transition of the voltage Vdd ends at 1 E-5 seconds, that this device experiences a much greater power fluctuation of about 1.5 dBm before settling to 0 dBm. From FIG. 4 it is clear that the body contact regions 204 and 206 either speed up the release of trapped electrons 208 and/or reduces the probability of trapping such electrons in the substrate.

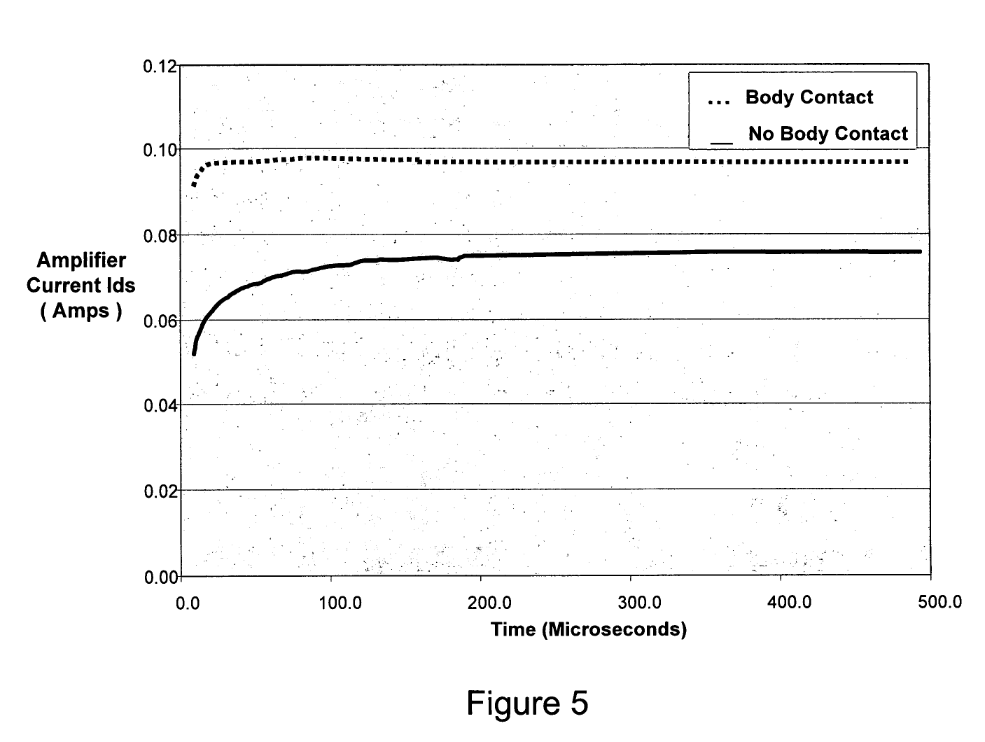

FIG. 5 is a graph illustrating drain-to-source or channel current Ids as a function of time for an MMIC including the MESFET 200 of FIG. 2 which shows the reduced gate lag of the MESFET when a rapid change in gate-to-source voltage occurs. In this graph, at a time zero the gate-to-source voltage Vgs applied to a circuit including MESFETs 200 is increased. A solid line in the graph shows a slow response of the drain-to-source Ids current in a circuit containing MESFETs having no body contact regions 204 and 206. For such device, the graph illustrates that it takes more than 100 microseconds for the current Ids to approach a steady state. Conversely, another circuit incorporates MESFETs 200 including the drain and source body contact regions 204 and 206 (FIG. 2). A dotted line shows that for these devices the rise time of the current Ids is now reduced by more than 10×, to less than 10 microseconds. In the example of FIG. 5 the dotted line actually corresponds to an amplifier circuit where the output transistor, which would be the largest transistor in the circuit, includes the drain and source body contact regions 204 and 206. Implementation of body contact regions 204 and 206 in all the transistors of such an amplifier circuit would further reduce the rise time of the current Ids.

Note that although the embodiment of the MESFET 200 illustrated in FIG. 2 includes drain and source body contact regions 204, another embodiment of the present invention includes only the drain body contact region 204. This embodiment accordingly includes no source body contact region 206. A further embodiment includes only the source body contact region 206 and no drain body contact region 204. In embodiments of the present invention, a body contact region to the drain side of the device acts more effectively than a body contact region to the source side. The maximum transient reduction, however, is realized when both body contact regions are present. This indicates that electrically grounding the substrate 202 to the source region 218 significantly helps in setting up conditions favorable to fast release of trapped charges in the substrate. Finally, one skilled in the art will understand suitable processes for forming the MESFET 200, including various techniques for forming the body contact regions 204 and 206.

Even though various embodiments and advantages of the present invention have been set forth in the foregoing description, the above disclosure is illustrative only, and changes may be made in detail and yet remain within the broad principles of the present invention. Many of the specific details of these embodiments of the invention have been set forth simply to provide a thorough understanding of such embodiments and one skilled in the art will understand, however, that the present invention may be practiced without several of the details described in the following description. Moreover, it should be understood that the figures related to the various embodiments are not to be interpreted as conveying any specific or relative physical dimensions, and that specific or relative physical dimensions, if stated, are not to be considered limiting unless the claims expressly state otherwise. The present invention is accordingly to be limited only by the appended claims.

What is claimed is:

1. A field effect transistor formed on a substrate, the transistor comprising:
a semiconductor channel region formed over the substrate;
a metallic source region formed on the channel region;
a metallic drain region formed on the channel region;
a metallic gate region formed on the channel region between the source and drain regions; and
a first metallic body contact region formed adjacent the drain region and extending through the channel region to contact the substrate.

2. The field effect transistor of claim 1 further comprising a second metallic body contact region formed adjacent the source region and extending through the channel region to contact the substrate.

3. The field effect transistor of claim 2 wherein the drain region is electrically coupled to the first metallic body contact region and the source region is electrically coupled to the second metallic body contact region.

4. The field effect transistor of claim 2 wherein the metallic source and drain regions each form a Schottky contact between the respective region and the semiconductor channel region.

5. The field effect transistor of claim 1 wherein the channel region comprises a III-V semiconductor material.

6. The field effect transistor of claim 5 wherein the III-V semiconductor material comprises gallium arsenide (GaAs).

7. The field effect transistor of claim 1 further comprising a buffer layer formed between the substrate and the channel region.

8. An electronic device, comprising:
an integrated circuit including a plurality of field effect transistors formed on a substrate, at least some of the field effect transistors including,
a semiconductor channel region formed over the substrate;
a metallic source region formed on the channel region;
a metallic drain region formed on the channel region;
a metallic gate region formed on the channel region between the source and drain regions; and
a first metallic body contact region formed adjacent the drain region and extending through the channel region to contact the substrate.

9. The electronic device of claim 8 wherein the integrated circuit includes communications circuitry.

10. The electronic device of claim 9 wherein the communications circuitry comprises wireless communications circuitry that utilizes code division multiple access (CDMA) or wideband CDMA communications protocols.

11. The electronic device of claim 10 wherein the electronic device comprise a cellular telephone or portable digital assistant.

12. The electronic device of claim 8 wherein at least some of the field effect transistors further comprises a second metallic body contact region formed adjacent the source region and extending through the channel region to contact the substrate.

13. A method of forming a field effect transistor on a substrate, the method comprising:
forming a semiconductor channel layer over the substrate;
forming metallic source and drain regions on the channel region;
forming a metallic gate region on the channel layer, the metallic gate region being positioned between the source and drain regions;
forming a first trench adjacent the drain region, the first trench extending through the channel layer to the substrate; and
forming in the first trench a first metallic body contact region.

14. The method of claim 13 further comprising:
forming a second trench adjacent the source region, the second trench extending through the channel layer to the substrate; and
forming in the second trench a second metallic body contact region.

15. The method of claim 14 wherein forming the first and second trenches comprises etching the channel layer.

16. The method of claim 14 further comprising applying a first same voltage to the drain region and the first metallic body contact region and applying a second same voltage to the source region and the second metallic body contact region.

17. The method of claim 13 further comprising:
prior to forming semiconductor channel layer over the substrate, forming a buffer layer on the substrate and thereafter forming the channel layer on the buffer layer; and
wherein the operation of forming the first trench includes removing portions of the buffer layer so that the first trench extends through the channel layer and buffer layer and to the substrate.

18. The method of claim 13 further comprising doping the substrate with either an n-type material or a p-type material.

19. The method of claim 13 wherein forming the channel layer comprises depositing a III-V semiconductor material on the substrate.

20. The method of claim 19 wherein depositing the III-V semiconductor material comprises depositing gallium arsenide (GaAs).
